(19) United States
(12) Patent Application Publication
(10) Pub. No.: US 2026/0343791 A1
(43) Pub. Date: Oct. 29, 2026

(54) ELECTRONIC DEVICE

(71) Applicant: DENSO CORPORATION, Kariya-city (JP)

(72) Inventor: Mikito OGUSU, Kariya-city (JP)

(21) Appl. No.: 19/651,117

(22) Filed: Apr. 17, 2026

(30) Foreign Application Priority Data
Apr. 24, 2025 (JP) 2025-072546

(51) Int. Cl. H05K 7/20

(52) U.S. Cl. CPC H05K 7/20154

(57) ABSTRACT

An electronic device includes a housing, a cover portion, a fan device, a first air-intake vent, and a restricting section. The housing accommodates a heat-generating component and has a cooling wall facing the heat-generating component. The cover portion covers the cooling wall. The cover portion and the cooling wall define a flow path for cooling medium between the cover portion and the cooling wall. The fan device is attached to the cover portion and configured to cause the cooling medium to flow in the flow path. The first air-intake vent is defined by the housing and the cover portion and communicating with the flow path. The restricting section is formed on at least one of the housing or the cover portion, and configured to restrict inflow of the cooling medium into the flow path. The restricting section includes a second air-intake vent communicating with the flow path.

### CROSS REFERENCE TO RELATED APPLICATION

The present application claims the benefit of priority from Japanese Patent Application No. 2025-072546 filed on Apr. 24, 2025. The entire disclosure of the above application is incorporated herein by reference.

### TECHNICAL FIELD

The present disclosure relates to an electronic device.

### BACKGROUND

An electronic control unit is described as an example of an electronic device.

### SUMMARY

An electronic device includes a housing, a cover portion, a fan device, a first air-intake vent, and a restricting section. The housing accommodates a heat-generating component and has a cooling wall facing the heat-generating component. The cover portion covers the cooling wall. The cover portion and the cooling wall define a flow path for cooling medium between the cover portion and the cooling wall. The fan device is attached to the cover portion and configured to cause the cooling medium to flow in the flow path. The first air-intake vent is defined by the housing and the cover portion and communicating with the flow path. The restricting section is formed on at least one of the housing or the cover portion, and configured to restrict inflow of the cooling medium into the flow path. The restricting section includes a second air-intake vent communicating with the flow path.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a perspective view showing a schematic configuration of an electronic control device.

FIG. 2 is an exploded perspective view showing the schematic configuration of the electronic control device.

FIG. 3 is a perspective view from a back surface of a cover.

FIG. 4 is a planar view showing a schematic configuration of a housing.

FIG. 5 is a cross-sectional view taken along a line V-V in FIG. 1.

FIG. 6 is an enlarged cross-sectional view of a VI-VI region in FIG. 5.

FIG. 7 is a cross-sectional view showing a schematic configuration of a restricting section according to a first modification.

FIG. 8 is a cross-sectional view showing a schematic configuration of a restricting section according to a second modification.

FIG. 9 is a planar view showing a schematic configuration of a housing according to a third modification.

FIG. 10 is a perspective view showing a schematic configuration of an electronic control device according to a fourth modification.

### DESCRIPTION OF EMBODIMENTS

To begin with, an example of relevant techniques will be described. An electronic control unit is described as the example of an electronic device. The electronic control unit includes a housing, a fin cover, and an air-cooling fan. The housing includes an upper housing and a lower housing. The fin cover is disposed to cover an upper side of heat sink fins provided in the upper housing. The air-cooling fan is attached to the upper housing. The housing has a forced air-cooling structure including the air-cooling fan.

An electronic device may include a fan and an air-intake vent. In this case, when the air-intake vent of the electronic device is blocked by foreign matter, the cooling air can not be drawn in. As a result, cooling performance of the electronic device may decrease.

In contrast to the comparative example, according to the present disclosure, an electronic device is capable of maintaining cooling performance.

An electronic device of the present disclosure includes a housing, a cover portion, a fan device, a first air-intake vent, and a restricting section. The housing accommodates a heat-generating component and has a cooling wall facing the heat-generating component. The cover portion covers the cooling wall. The cover portion and the cooling wall define a flow path for cooling medium between the cover portion and the cooling wall. The fan device is attached to the cover portion and configured to cause the cooling medium to flow in the flow path. The first air-intake vent is defined by the housing and the cover portion and communicating with the flow path. The restricting section is formed on at least one of the housing or the cover portion, and configured to restrict inflow of the cooling medium into the flow path. The restricting section includes a second air-intake vent communicating with the flow path.

According to the electronic device, even if the first air-intake vent is blocked by foreign matter, the electronic device can still draw in air from the second air-intake vent into flow path.

The embodiments of the present disclosure will be described below with reference to the drawings. In the following embodiments, portions that are the same as or equivalent to those described in a preceding embodiment are denoted by the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

Hereinafter, multiple embodiments for carrying out the present disclosure will be described with reference to the drawings. In each embodiment, portions corresponding to those described in the preceding embodiment are denoted by the same reference numerals, and redundant descriptions will be omitted in some cases. In each embodiment, in a case where only a part of the configuration is described, another preceding embodiment can be referenced to and applied to the other parts of the configuration. Hereinafter, three directions perpendicular to each other are denoted as an X direction, a Y direction, and a Z direction.

### Embodiment

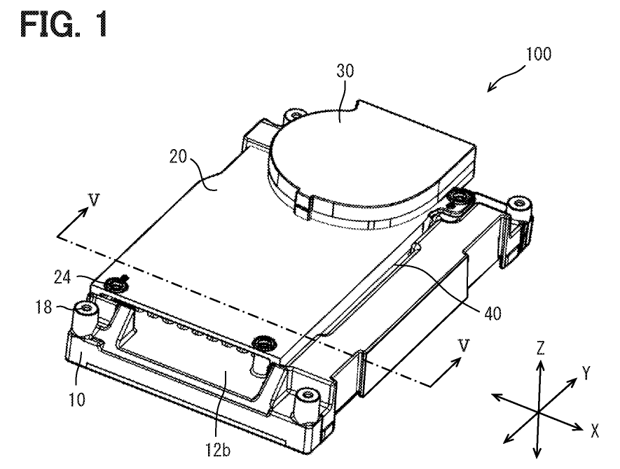

An electronic control device 100 of the present embodiment will be described with reference to FIGS. 1-6. In the present embodiment, the electronic control device 100 is adopted as an example of an electronic device. The electronic control device 100 is configured, for example, to be mountable on a mobile object. The mobile object is, for example, a vehicle such as an electric vehicle, hybrid vehicle, and fuel cell vehicle, a flying object, such as an electric vertical take-off and landing aircraft and drone, a ship, construction machinery, and agricultural machinery. In the present embodiment, a vehicle is adopted as an example of the mobile object. The electronic control device 100 is fixed to a mounting target section that is a part of the vehicle. The electronic device can be applied to other devices than the electronic control device 100.

The electronic control device 100 includes a housing 10, a cover 20, a fan device 30, and a circuit board 60. The electronic control device 100 is configured to cool the circuit board 60 using cooling medium such as air. The air used as the cooling medium is cooling air.

Output signals from sensors and other electronic devices installed in the vehicle are input to the electronic control device 100. In addition, the electronic control device 100 outputs control signals to in-vehicle devices installed in the vehicle. The electronic control device 100 is also referred to as an ECU. ECU is an abbreviation for Electronic Control Unit.

The housing 10 accommodates the circuit board 60. The housing 10 includes, for example, a base member and a cover member. The base member is a recessed member in which the circuit board 60 can be disposed. The base member includes an opening in a region facing the circuit board 60 in a Z direction.

The cover member is assembled to the base member so as to close the opening. The housing 10 defines an accommodating space for housing the circuit board 60 by assembling the cover member to the base member. The housing 10 is mainly made of a metal such as aluminum. However, the housing 10 may also be mainly made of a resin. The housing 10 may also have a configuration different from that described above.

As shown in FIGS. 1, 2, and 4, the housing 10 includes a housing base 11, multiple heat sink fins 12a provided on the housing base 11, and a side wall portion 15 provided on the housing base 11. The housing base 11 is arranged to face one surface of the circuit board 60. The housing base 11 can be regarded as a part of the cover member.

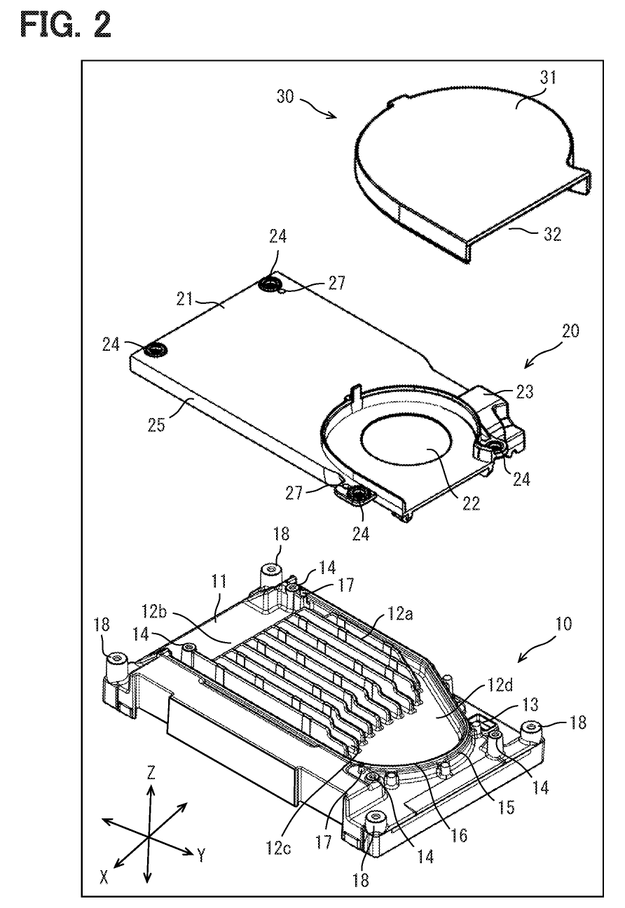

As shown in FIG. 2, the multiple heat sink fins 12a and the side wall portion 15 are disposed to protrude from an outer surface of the housing base 11 in the Z direction. A portion of the housing base 11 faces the one surface of the circuit board 60 and has the outer surface along an XY plane. The outer surface is a surface opposite to an inner surface of the housing base 11, which faces the accommodation space. The outer surface is a surface in contact with flow paths 12c and 12d, which will be described later. The XY plane is a virtual plane defined by an X-axis in an X direction and a Y-axis in a Y direction. The housing base 11 corresponds to a cooling wall.

The heat sink fins 12a are disposed to protrude from the outer surface of the housing base 11 in the Z direction. Each heat sink fin 12a extends in the Y direction. The heat sink fins 12a are arranged side by side in the X direction.

The heat sink fins 12a are disposed to increase heat dissipation area. In other words, the housing 10 can efficiently transfer heat from heat-generating components, which will be described later, to air, by the heat sink fins 12a. The air here is defined as air flowing through the flow paths 12c and 12d.

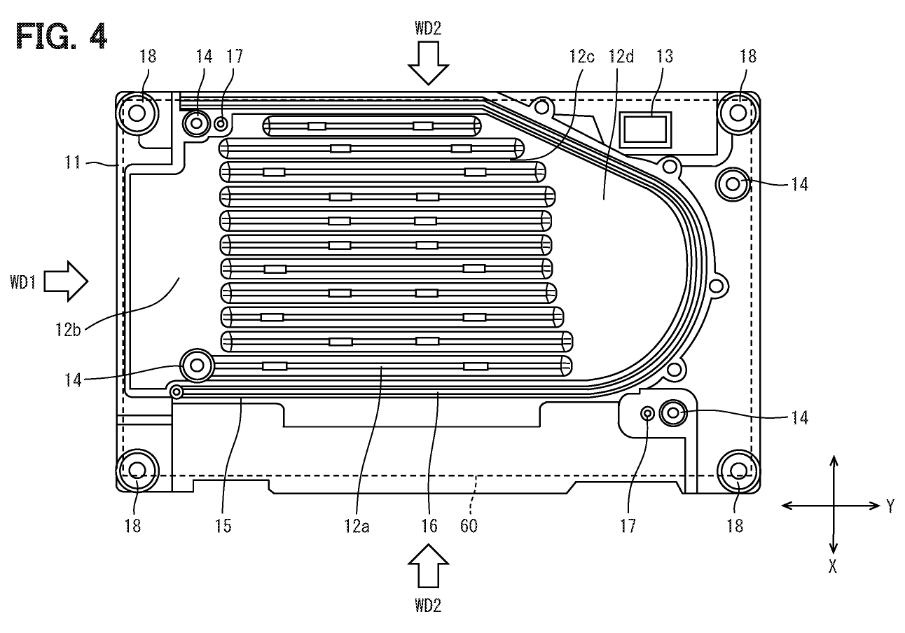

As shown in FIGS. 2 and 4, the side wall portion 15 is disposed to partially surround the multiple heat sink fins 12a. One side of the side wall portion 15 in the Y direction is interrupted around all the heat sink fins 12a. The side wall portion 15 is interrupted to define a main air-intake vent 12b. The main air-intake vent 12b corresponds to a first air-intake vent.

The side wall portion 15 includes portions disposed on opposite sides of all the heat sink fins 12a in the X direction. Furthermore, the other side of the side wall portion 15 in the Y direction includes a portion facing all the heat sink fins 12a. Both of the portions are continuously disposed. Additionally, the side wall portion 15 can also be said to include the two portions disposed in the Y direction, and the portion connected to one end of each of the two portions. The heat sink fins 12a are all disposed between the two portions.

As shown in FIG. 6, the side wall portion 15 is covered by the cover 20. The side wall portion 15 is disposed to face a side wall portion 25 of the cover 20 in the Z direction. Additionally, side wall edge-portions 16 and 26 are disposed to face each other in the Z direction. The electronic control device 100 includes a sub air-intake vent 40 defined by side wall portions 15 and 25 and the side wall edge-portions 16 and 26. The side wall portions 15 and 25 and the side wall edge-portions 16 and 26 constitute a restricting section 50. The cover 20, the sub air-intake vent 40, and the restricting section 50 will be described in detail later. In other words, the side wall portions 15 and 25 and the side wall edge-portions 16 and 26 will be described in detail later. The sub air-intake vent 40 corresponds to a second air-intake vent.

As shown in FIGS. 2 and 4, the first flow paths 12c have paths defined between heat sink fins 12a adjacent to each other. In addition, the first flow paths 12c have also paths defined between the heat sink fins 12a and the side wall portion 15. The first flow paths 12c extend in the Y direction.

In the Y direction, a second flow path 12d is defined between the heat sink fins 12a and the side wall portion 15. The second flow path 12d is an area that faces a fan device 30 and a vent 22, which will be described later. The first flow paths 12c and the second flow path 12d correspond to flow paths for the cooling medium. The first flow paths 12c and the second flow path 12d are also referred to as flow paths 12c and 12d, respectively.

The first flow paths 12c communicate with the main air-intake vent 12b and the second flow path 12d. Thus, the electronic control device 100 includes a space that extends from the main air-intake vent 12b to the second flow path 12d, through the first flow paths 12c. That space is a region through which the cooling air flows. The flow paths 12c and 12d are regions sandwiched between the housing base 11 and the cover 20 in the Z direction. The flow paths 12c and 12d are the regions between the housing base 11 and the cover 20. The first flow paths 12c can be said to communicate with the main air-intake vent 12b and the second flow path 12d.

In addition, the housing base 11 includes sections such as a connector section 13, fixing sections 14, positioning sections 17, and fixing sections 18. The connector section 13 is a through-hole passing through the housing base 11 in the Z direction. The connector section 13 is disposed to face a connector section 23 of the cover 20. A portion of the cable that electrically connects a fan motor and the circuit board 60 is disposed in the connector section 13. In other words, the connector section 13 is disposed to route the cable from the circuit board 60 disposed in the accommodation space to the fan device 30.

The fixing sections 14 are disposed to face fixing sections 24 of the cover 20. The fixing sections 14 and the fixing sections 24 are sections for securing the cover 20 to the housing base 11. The cover 20 is fixed to the housing base 11, for example, by a screw member. A female screw is provided in each of the fixing sections 14. Each of the fixing sections 24 is a through-hole into which the screw member is inserted. However, the cover 20 may also be secured to the housing base 11 by fitting or other means.

The positioning sections 17 are disposed to face positioning sections 27 of the cover 20. Each of the positioning sections 17 is a protrusion that protrudes relative to its surroundings. Each of the positioning sections 27 is a recess that is recessed relative to its surroundings. The cover 20 is positioned at a proper location of the housing base 11 by the positioning sections 17 being inserted into the positioning sections 27. In other words, the cover 20 and the housing base 11 are positioned by the positioning sections 17 and 27. In the present disclosure, the positioning sections 17 may be the recess and the positioning sections 27 may be the protrusion.

The fixing sections 18 are parts for securing the electronic control device 100 to the mounting target portion. The electronic control device 100 is fixed, for example, by a screw member. Each of the fixing section 18 is a hole into which the screw member is inserted. The mounting target portion includes female screws. However, the electronic control device 100 may also be secured to the mounting target portion by fitting or the like.

The cover 20 is disposed to cover the housing base 11. The cover 20 can also be regarded as a member that defines the flow paths 12c and 12d between the housing base 11 and the cover 20. Furthermore, it can also be said that the main air-intake vent 12b is defined by the housing 10 and the cover 20. The cover 20 corresponds to a cover portion.

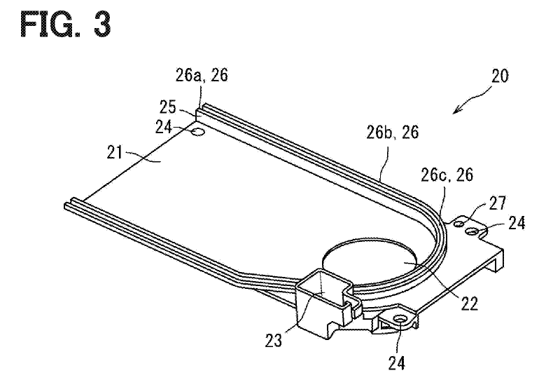

As shown in FIGS. 2 and 3, the cover 20 includes a cover base 21 and the side wall portion 25 continuous with the cover base 21. Furthermore, as described above, the cover 20 includes the connector section 23, the fixing sections 24, and the positioning sections 27.

The cover base 21 is disposed to face the multiple heat sink fins 12a. The cover base 21 includes a vent 22 at a location facing the second flow path 12d. The vent 22 is a through-hole provided in the cover base 21.

The side wall portion 25 is disposed to face the side wall portion 15 as described above. One side of the side wall portion 25 in the Y direction is interrupted, on an annular edge-portion of the cover base 21, similar to the side wall portion 15. It can also be said that the side wall portion 25 and the side wall portion 15 have U-shapes in planar view. The side wall edge-portion 26 of the side wall portion 25 includes a wall portion 26a, a wall portion 26b, and a bottom portion 26c.

The fan device 30 is a device for causing air to flow through the flow paths 12c and 12d. The fan device 30 includes a fan motor, a fan mounted on a rotary shaft of the fan motor, and a fan cover 31 that surrounds the fan. The fan motor is electrically connected to the circuit board 60 via the cable.

Connectors are provided at opposite ends of the cable. One connector is connected to the fan motor. The other connector is connected to the circuit board 60. The cable passes through the connector sections 13 and 23, connecting the fan motor to the circuit board 60 within the housing 10.

The fan motor is driven and controlled by control signals from the circuit board 60. In other words, the rotary shaft of the fan motor rotates or stops in response to the control signals. The fan device 30 is configured so that the fan rotates when the rotary shaft rotates. Furthermore, the fan device 30 is configured so that the fan stops rotating when the rotation shaft stops. Hereinafter, for convenience, rotation of the rotary shaft or stop of the rotary shaft will also be referred to as the rotation of the fan device 30 and the stop of the fan device 30, respectively.

As shown in FIGS. 1 and 2, the fan cover 31 is attached to the cover 20. Specifically, the fan cover 31 is attached to a portion of the cover base 21. Furthermore, the fan cover 31 is attached at a position facing the vent 22 provided in the cover base 21. The fan cover 31 is attached to the cover base 21 by fitting or the like.

The fan cover 31 includes an exhaust vent 32 through which air flows out. The exhaust vent 32 can also be regarded as a space (opening) between the fan cover 31 and the cover base 21. Furthermore, the electronic control device 100 defines the exhaust vent 32 between the fan cover 31 and the cover base 21, when the fan cover 31 is attached to the cover base 21.

The fan device 30 draws in air from an external environment of the electronic control device 100 through the main air-intake vent 12b by the fan rotating. Furthermore, the fan device 30 exhausts the air drawn in from the main air-intake vent 12b to the external environment through the exhaust vent 32 via the flow paths 12c, 12d, and the vent 22. In this way, the fan device 30 makes an airflow from the main air-intake vent 12b through the flow paths 12c, 12d and the vent 22 to the exhaust vent 32. As a result, the fan device 30 cools the heat-generating components.

The circuit board 60 includes a wiring board, circuit elements and connectors mounted on the wiring board. The wiring board has one surface along an XY plane, the other surface opposite to the one surface, and a side surface continuous with the one surface and the other surface. The one surface is a surface facing the housing base 11, and may also be referred to as a facing surface. The circuit elements and connectors are mounted on the one surface or the other surface of the wiring board.

The circuit elements include a microcontroller and passive components such as capacitors and resistors. The microcontroller includes a processing unit such as a CPU, a storage device, such as SRAM and flash memory, and a communication interface. CPU is an abbreviation for Central Processing Unit. SRAM is an abbreviation for Static Random Access Memory.

The circuit board 60 is electrically connected to sensors and other electronic devices via the connectors. Thus, output signals from the sensors and other electronic devices are input to the circuit board 60. In addition, the circuit board 60 is electrically connected to an external power supply via a connector. The circuit board 60 is supplied with power from the external power supply.

For example, the circuit board 60 includes the processing unit executing a program stored in the storage device. The processing unit performs computations by executing the program. The processing unit performs computations while utilizing output signals input to the communication interface and data stored in the storage device, among other information. The processing unit calculates control signals through the computations. The processing unit outputs the control signals to the in-vehicle device via the communication interface.

Furthermore, the processing unit calculates control signals for driving and controlling the fan motor. The processing unit outputs control signals to the fan motor via the communication interface. Thus, the circuit board 60 has a function for driving and controlling the fan device 30.

The microcontroller generates heat during operation. Thus, the microcontroller is also referred to as a heat-generating component. The circuit board 60 may also include heat-generating components other than the microcontroller. The heat-generating components other than the microcontroller include semiconductor switching elements and IC chips.

The heat-generating components may need to be mounted on the one surface from a perspective of heat dissipating performance. In other words, the heat-generating components are arranged to face the heat sink fins 12a and the flow paths 12c and 12d, by being mounted on the one surface. Thus, the heat-generating components are efficiently cooled by air. The circuit board 60 itself can be regarded as a heat-generating component.

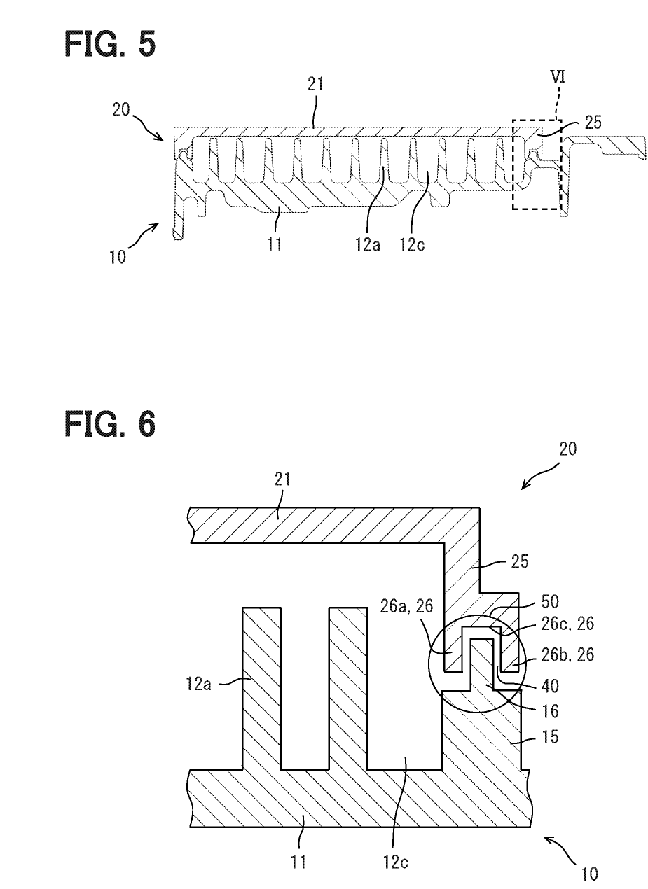

Here, the sub air-intake vent 40 and the restricting section 50 will be described with reference to FIGS. 5 and 6. FIG. 6 is a cross-sectional view taken along an XZ plane. The XZ plane is a virtual plane defined by the X-axis and a Z-axis which extends in the Z direction. The side wall edge-portions 16 and 26, for example, have the same shape at both the one end and the other end of the side wall portions 15 and 25. In FIG. 6, the side wall edge-portions 16 and 26 are illustrated in a simplified manner.

As shown in FIG. 6, the side wall edge-portion 26 is a portion provided at an edge of the side wall portion 25. The side wall edge-portion 26 have the wall portion 26a, the wall portion 26b, and the bottom portion 26c. The wall portions 26a and 26b are portions that protrude from the bottom portion 26c. The side wall edge-portion 26 has a recessed cross-sectional shape. The side wall edge-portion 26 includes a groove defined by the wall portion 26a, the wall portion 26b, and the bottom portion 26c.

The side wall edge-portion 16 is a portion disposed at an edge of the side wall portion 15. The side wall edge-portion 16 is a portion protruding relative to its surroundings. The side wall edge-portion 16 includes a narrower width than a portion of the side wall portions 15 other than the side wall edge-portion 16. The width of the side wall edge-portion 16 is less than a distance between the wall portions 26a and 26b.

In the restricting section 50, the side wall edge-portion 16 is disposed between the wall portions 26a and 26b. In other words, the side wall edge-portion 16 is disposed to face the bottom portion 26c in the Z direction. In addition, it can be said that the side wall edge-portion 16 is also disposed in the groove in the side wall edge-portion 26. The side wall edge-portion 16 is disposed with a distance from the bottom portion 26c in the Z direction. The distance between the side wall edge-portion 16 and the bottom portion 26c in the Z direction can also be referred to as a first space.

In addition, the side wall edge-portion 16 is disposed to face the wall portions 26a and 26b in a direction along the XY plane (hereinafter referred to as an XY direction). The side wall edge-portion 16 is disposed with a distance from the wall portions 26a and 26b in the XY direction. The distance between the side wall edge-portion 16 and the wall portion 26a in the XY direction, and the distance between the side wall edge-portion 16 and the wall portion 26b in the XY direction, can also be referred to as a second space. The second space is communicated with the first space.

The wall portions 26a and 26b are arranged to face the side wall portion 15 in the Z direction. In other words, the wall portions 26a and 26b are arranged to face the peripheral region of the side wall edge-portion 16 of the side wall portion 15 in the Z direction. The wall portions 26a and 26b are arranged with a distance from the side wall portion 15 in the Z direction. The distance between the wall portion 26a and the side wall portion 15 in the Z direction, and the distance between the wall portion 26b and the side wall portion 15 in the Z direction, can also be referred to as a third space. The third space is communicated with the second space.

In the restricting section 50, the sub air-intake vent 40 is defined by the side wall edge-portion 16 and the side wall edge-portion 26. The sub air-intake vent 40 is a distance between the side wall edge-portion 16 and the side wall edge-portion 26. In other words, the sub air-intake vent 40 consists of the first space, the second space, and the third space. The sub air-intake vent 40 communicates with the flow paths 12c and 12d. The sub air-intake vent 40 is disposed to draw in air from the external environment into the flow paths 12c and 12d in a case where the main air-intake vent 12b is blocked by foreign matter.

The present embodiment, as an example, adopts the sub air-intake vent 40 that is a four-turn crank type (FIG. 6). The sub air-intake vent 40 can also be said to have a labyrinth-seal shape. As a result, when the main air-intake vent 12b is not blocked by foreign matter, air is not likely to flow in through the sub air-intake vent 40. Thus, the electronic control device 100 can draw in air from the main air-intake vent 12b, thereby reducing a decrease in cooling effect of the heat-generating components.

However, the restricting section 50 may be configured such that the sub air-intake vent 40 has a three-turn crank structure. Similarly to in a case where the sub air-intake vent 40 is the four-turn crank type, the sub air-intake vent 40 can also be said to have a labyrinth-seal shape. In this case, the side wall portion 15 does not have a portion facing the wall portion 26b in the Z direction. In other words, the restricting section 50 may be constituted by the side wall portion 25 including the above-mentioned side wall edge-portion 26, and the side wall portion 15 including the side wall edge-portion 16 of a first modification, which is described later.

Hereinafter, a state where the main air-intake vent 12b is not blocked by foreign matter is also referred to as a normal state. In addition, a state where the main air-intake vent 12b is blocked by foreign matter is also referred to as an abnormal state.

The sub air-intake vent 40 is an opening for drawing air into the flow paths 12c and 12d, similarly to the main air-intake vent 12b. However, the sub air-intake vent 40 is smaller than the main air-intake vent 12b. The sub air-intake vent 40 is sized such that air is drawn mainly from the main air-intake vent 12b by rotation of the fan device 30, in the normal state.

The sub air-intake vent 40 has a smaller opening area than that of the main air-intake vent 12b. The opening area of the main air-intake vent 12b is an area of the opening along the XZ plane. The opening area of the sub air-intake vent 40 is, for example, an area between the side wall portion 15 and the wall portion 26b. The sub air-intake vent 40 can be said to have an opening area such that intake of air from the main air-intake vent 12b is not hindered.

As a result, the electronic control device 100 can more easily draw in the cooling medium from the main air-intake vent 12b than from the sub air-intake vent 40, in the normal state. Thus, the electronic control device 100 can reduce a decrease in the cooling effect of the heat-generating components.

The restricting section 50 is a section that restricts an inflow of air from the external environment into the flow paths 12c and 12d. The restricting section 50 does not completely block the inflow of air into the flow paths 12c and 12d. The restricting section 50 is a section that restricts the intake from the sub air-intake vent 40 so that air can be mainly drawn in through the main air-intake vent 12b, by the rotation of the fan device 30. In other words, the restricting section 50 can also be referred to as a section that restricts the inflow of air from the outside into the flow paths 12c. Thus, the restricting section 50 may also be referred to as a limiting section.

In the normal state, the electronic control device 100 draws in air from the main air-intake vent 12b by the rotation of the fan device 30. Thus, the electronic control device 100 draws in air in a first direction WD1, as shown in FIG. 4. Then, the air drawn in from the main air-intake vent 12b flows through the flow paths 12c and 12d, and is exhausted from the exhaust vent 32. The electronic control device 100 can cool the heat-generating components using air drawn in from the main air-intake vent 12b.

The electronic control device 100 may need to be able to mainly draw in air from the main air-intake vent 12b, in the normal state. Thus, the electronic control device 100 may also draw in air from the sub air-intake vent 40 in the normal state. However, an amount of air drawn in from the sub air-intake vent 40 is significantly less than an amount of air drawn in from the main air-intake vent 12b, in the normal state.

On the other hand, the electronic control device 100 draws in air from the sub air-intake vent 40 by the rotation of the fan device 30, in the abnormal state. Thus, the electronic control device 100 draws in air in a second direction WD2, as shown in FIG. 4. Then, air drawn in from the sub air-intake vent 40 flows through the flow paths 12c and 12d and is exhausted from the exhaust vent 32. The electronic control device 100 can cool the heat-generating components using air drawn in from the sub air-intake vent 40.

In this embodiment, the restricting section 50 defined by the housing 10 and the cover 20 is employed as an example. However, the restricting section 50 may need to be defined by at least one of the housing 10 or the cover 20.

### Effects

As described above, even if the main air-intake vent 12b is blocked by foreign matter, the electronic control device 100 can still draw in air from the sub air-intake vent 40 into flow paths 12c and 12d. Therefore, the electronic control device 100 can cool the heat-generating components. In this way, the electronic control device 100 can maintain its cooling performance.

The embodiment of the present disclosure has been described above. However, the present disclosure is not limited to the above embodiment. Various modifications may be made without departing from the scope and spirit of the present disclosure. First to fourth modifications will be described as the other embodiments of the present disclosure in the following. The above embodiment and first to fourth modifications can be implemented individually, or may be appropriately combined and implemented. The present disclosure is not limited to combinations disclosed in the above-described embodiment but can be implemented in various combinations.

### First Modification

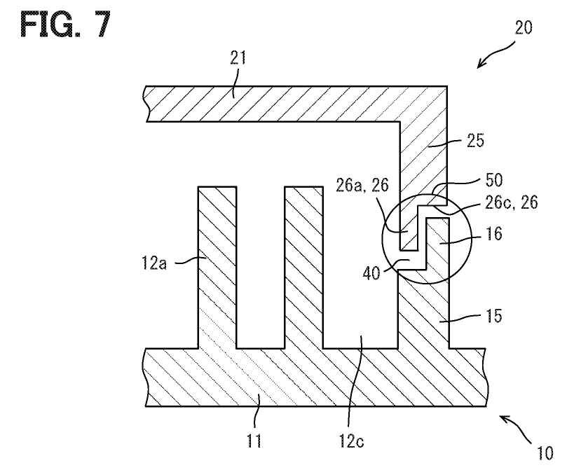

As shown in a first modification of FIG. 7, the electronic control device 100 may include a restricting section 50 configured such that a sub air-intake vent 40 is a two-turn crank type. The sub air-intake vent 40 can also be said to have a labyrinth-seal shape. FIG. 7 is a cross-sectional view corresponding to FIG. 6.

A side wall edge-portion 26 has a wall portion 26a and a bottom portion 26c. The side wall edge-portion 26 in the first modification does not have the wall portion 26b, unlike the above embodiment. The wall portion 26a is a portion that protrudes from the bottom portion 26c. A side wall edge-portion 16 is a portion that protrudes from its surroundings. The side wall edge-portion 16 has a narrower width than that of a portion of a side wall portion 15 other than the side wall edge-portion 16.

Similarly to the above embodiment, the side wall edge-portion 16 is disposed to face the bottom portion 26c in the Z direction. In the Z direction, a first space is defined between the side wall edge-portion 16 and the bottom portion 26c.

Furthermore, similarly to the above embodiment, the side wall edge-portion 16 is disposed to face the wall portion 26a in the XY direction. In the XY direction, a second space is defined between the side wall edge-portion 16 and the wall portion 26a.

Similarly to the above embodiment, the wall portion 26a is disposed to face the side wall portion 15 in the Z direction. In the Z direction, a third space is defined between the wall portion 26a and the side wall portion 15.

The sub air-intake vent 40 consists of the first space, the second space, and the third space. The electronic control device 100 of the first modification can achieve similar effects as the above embodiment.

### Second Modification

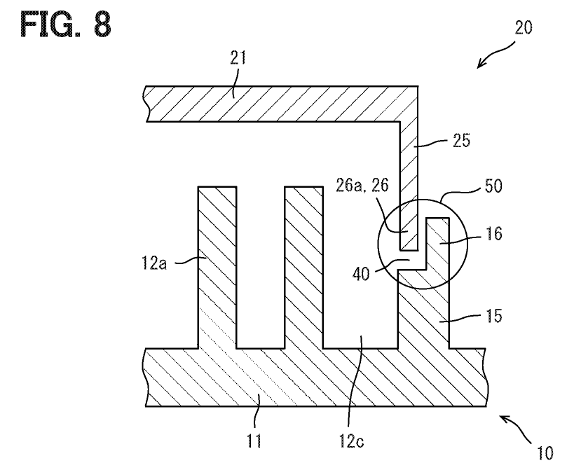

As shown in a second modification in FIG. 8, the electronic control device 100 may include a restricting section 50 configured such that a sub air-intake vent 40 is a one-turn crank type. The sub air-intake vent 40 can also be said to have a labyrinth-seal shape. FIG. 8 is a cross-sectional view corresponding to FIG. 6.

A side wall edge-portion 26 has a wall portion 26a. The side wall edge-portion 26 of the second modification does not have the wall portion 26b or the bottom portion 26c, unlike the above embodiment. A side wall portion 15 (side wall edge-portion 16) is similar to that in the first modification.

The side wall edge-portion 16 does not face the side wall portion 25 in the Z direction. Furthermore, the side wall edge-portion 16 is disposed to face the wall portion 26a in the XY direction, similarly to in the above embodiment. Therefore, the second space is defined between the side wall edge-portion 16 and the wall portion 26a in the XY direction.

Similarly to in the above embodiment, the wall portion 26a is disposed to face the side wall portion 15 in the Z direction. Therefore, the third space is defined between the wall portion 26a and the side wall portion 15, in the Z direction.

The sub air-intake vent 40 consists of by the second space and the third space. The electronic control device 100 of the second modification can achieve similar effects as the above embodiment.

### Third Modification

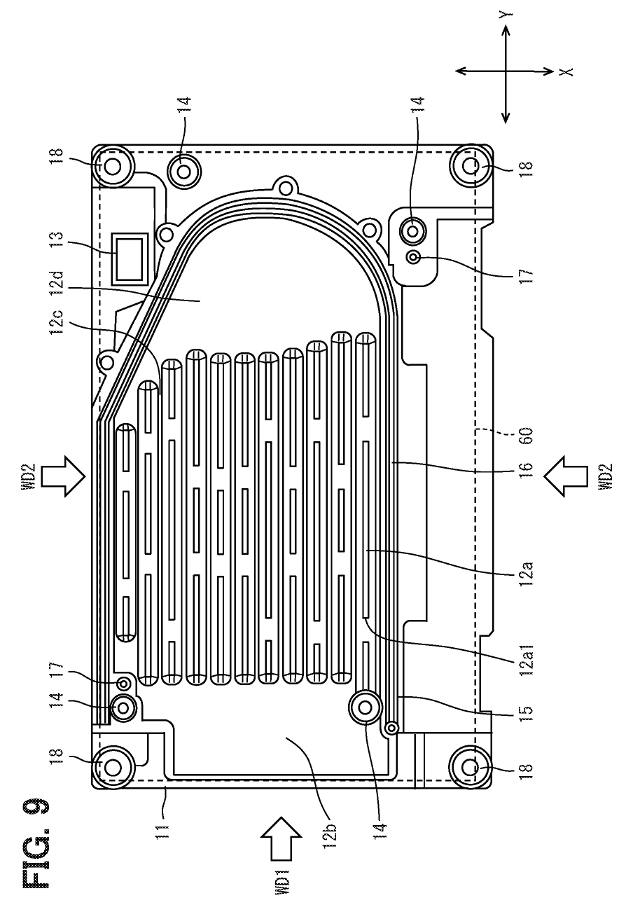

As shown in a third modification in FIG. 9, the electronic control device 100 may include heat sink fins 12a having slits 12a1. Each heat sink fin 12a is divided by the slits 12a1 in the Y direction.

As described above, the electronic control device 100 draws in air in a second direction WD2, in the abnormal state. Since each heat sink fin 12a of the electronic control device 100 includes the slits 12a1, air can flow more easily in the X direction. Therefore, air can flow more easily within the flow paths 12c and 12d in the electronic control device 100, in the abnormal state. Then, the electronic control device 100 can efficiently cool the heat-generating components, even in the abnormal state. The electronic control device 100 of the third modification can achieve similar effects as those of the above embodiment.

### Fourth Modification

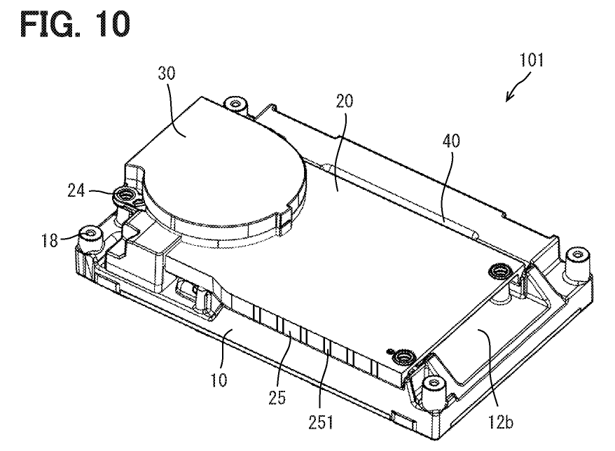

As shown in a fourth modification in FIG. 10, an electronic control unit 101 may include a cover 20 having openings 251. In other words, a sub air-intake vent 40 may include the openings 251 of the cover 20. The openings 251 are defined in a side wall portion 25. For example, the openings 251 are defined at multiple positions of the side wall portion 25. Furthermore, the electronic control unit 101 includes flow paths 12c and 12d communicating with the external environment through the openings 251. The electronic control unit 101 of the fourth modification can achieve similar effects as the above embodiment.

The electronic control unit 101 of the fourth modification may not include the first space, second space, and third space. In other words, the electronic control unit 101 of the fourth modification include the openings 251 as the sub air-intake vent 40. In this case, it can be said that the restricting section 50 is formed by the cover 20.

The embodiment of the present disclosure has been described above. The present disclosure is not limited to the above embodiments or structures. The present disclosure covers various modifications and equivalents. In addition, while various combinations and modes are described in the present disclosure, other combinations and modes including only one element, more elements, or less elements therein are also within the scope and spirit of the present disclosure.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. An electronic device comprising:
a housing that accommodates a heat-generating component and has a cooling wall facing the heat-generating component;
a cover portion covering the cooling wall, the cover portion and the cooling wall defining a flow path for cooling medium between the cover portion and the cooling wall;
a fan device attached to the cover portion and configured to cause the cooling medium to flow in the flow path;
a first air-intake vent defined by the housing and the cover portion and communicating with the flow path; and
a restricting section formed on at least one of the housing or the cover portion, and configured to restrict inflow of the cooling medium into the flow path, wherein
the restricting section includes a second air-intake vent communicating with the flow path.

2. The electronic device according to claim 1, wherein
the second air-intake vent is smaller than the first air-intake vent.

3. The electronic device according to claim 1, wherein
the second air-intake vent has a labyrinth-seal shape.

4. The electronic device according to claim 1, wherein
the second air-intake vent includes an opening provided on the cover.

5. The electronic device according to claim 1, wherein
the housing includes a heat sink fin protruding from the cooling wall, and
the heat sink fin includes a slit.

6. The electronic device according to claim 3, wherein
the flow path includes one or more bent portions.

7. The electronic device according to claim 1, wherein
the fan device and the cover portion define an exhaust vent communicating with the flow path.

8. The electronic device according to claim 1, wherein
the first air-intake vent facing in a first direction, and
the second air-intake vent facing in a second direction intersecting the first direction.

9. The electronic device according to claim 8, wherein
the housing includes a heat sink fin extending in the first direction, and
the heat sink fin includes a slit that faces in the second direction.
